(19) United States
(12) Patent Application Publication
(10) Pub. No.: US 2008/0310113 A1
(43) Pub. Date: Dec. 18, 2008

(54) Electronics rack and lithographic apparatus comprising such electronics rack

(75) Inventors: Edwin Gerardus Adrianus Johannes Renders, Eindhoven (NL); Kris Pierre Augusta Vandebriel, Lommel (BE); Petrus Jacobus Maria Van Gils, Berkel-Enschot (NL)

Correspondence Address: STERNE, KESSLER, GOLDSTEIN & FOX P.L.L.C., 1100 NEW YORK AVENUE, N.W., WASHINGTON, DC, 20005, US

(73) Assignee: ASML NETHERLANDS B.V., Veldhoven (NL)

(21) Appl. No.: 11/808,920

(22) Filed: Jun. 13, 2007

(51) Int. Cl. H05K 7/20

(52) U.S. Cl. 361/702

(57) ABSTRACT

A lithographic apparatus having an electronics module and an electronics rack in which the electronics module is operationally housed is disclosed. The electronics rack includes an electrical connector to establish an electrical connection to a mating electrical connector of the electronics module and a cooling fluid connector to establish a cooling fluid connection to a mating cooling fluid connector of the electronics module, wherein a direction of insertion of the mating electrical connector substantially corresponds to a direction of insertion of the mating cooling fluid connector.

### FIELD

The present invention relates to a lithographic apparatus comprising an electronics rack to house an electronics module, to a combination of such electronics rack and electronics module, and to such electronics module.

### BACKGROUND

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, maybe used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

Current developments in lithography trend toward higher throughput of a lithographic apparatus, in other words, shorter times to process a substrate (such as a wafer) by the lithographic apparatus. Processing time is influenced by many factors, including speed and acceleration of movement of stages (such as the substrate support to hold the substrate or the patterning device support to hold the patterning device). Acceleration and velocity are in turn affected by many parameters, including a maximum force to be generated by actuators to position and displace the substrate and/or patterning device support. To achieve high throughput, more and more powerful actuators may be used. The provision of a high power actuator typically means a high power amplifier to drive such an actuator.

Faster, and more accurate processing by a lithographic apparatus may require more powerful processing devices such as microprocessors, controllers, etc., which in turn may translate into a higher electrical power dissipation. A high pulse repetition laser providing high laser power may require matching driving and powering electronics, which may result in a tendency to increase power dissipation in electronic image control and electronic powering units of the lithographic apparatus.

The above are only a few examples to illustrate that a tendency can be found in lithography towards an increase in power dissipation of the lithographic apparatus, in particular in high power electronic and electronic modules such as processing and control units, power amplifiers, laser power and control devices, etc.

In present lithographic apparatus, use is made of fans or similar gas displacement devices to generate a gas stream to remove heat dissipated by electronic components. Normally, a lithographic apparatus is operated in a clean environment (“clean room”), where a floor space may be limited. Moreover, a supply of clean gas (clean air, clean artificial air, etc.), may be limited by gas conditioning and cleaning apparatuses provided in situ. Therefore, a limit is put on a maximum power dissipation permitted in typical clean room.

In lithography, electronics are commonly housed in modules to allow interchanging, testing, upgrading etc. of individual modules. Commonly, the modules are housed in a rack in which the modules are inserted. The rack, or a plurality of racks, may be mounted in a cabinet or other housing. Electrical connections may be provided via the rack, e.g., via a back plane or suitable connections thereof. The racks are commonly provided with a fan or a plurality of fans or other gas flow generating device to be able to keep the temperature of electrical and electronic components in the modules to an acceptable level.

### SUMMARY

It is desirable, for example, to provide an improved cooling mechanism for an electronics rack and an electronics module, e.g., forming part of a lithographic apparatus.

According to an embodiment of the invention, there is provided a lithographic apparatus comprising:

an illumination system configured to condition a radiation beam;

a support constructed to support a patterning device, the patterning device configured to impart the radiation beam with a pattern in its cross-section to form a patterned radiation beam;

a substrate support constructed to hold a substrate;

a projection system configured to project the patterned radiation beam onto a target portion of the substrate; and

an electronics module and an electronics rack in which the electronics module is operationally housed, the electronics rack comprising an electrical connector to establish an electrical connection to a mating electrical connector of the electronics module and a cooling fluid connector to establish a cooling fluid connection to a mating cooling fluid connector of the electronics module, wherein a direction of insertion of the mating electrical connector substantially corresponds to a direction of insertion of the mating cooling fluid connector.

According to an embodiment of the invention, there is provided a combination of an electronics module and an electronics rack to operationally accommodate the electronics module, the electronics rack comprising an electrical connector to establish an electrical connection to a mating electrical connector of the electronics module and a cooling fluid connector to establish a cooling fluid connection to a mating cooling fluid connector of the electronics module, wherein a direction of insertion of the mating electrical connector substantially corresponds to a direction of insertion of the mating cooling fluids connector.

According to an embodiment of the invention, there is provided an electronics module to be operated in an electronics rack, the electronics module comprising an electrical connector to establish an electrical connection to a mating electrical connector of the electronics rack and a cooling fluid connector to establish a cooling fluid connection to a mating cooling fluid connector of the electronics rack, wherein a direction of insertion of the electrical connector of the electronics module substantially corresponds to a direction of insertion of the cooling fluid connector of the electronics module.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 highly schematically depicts an electronic cabinet according to an aspect of the invention;

FIG. 3 highly schematically depicts a cross sectional top view of an electronics module according to an aspect of the invention for use with the rack of FIG. 2;

FIG. 4 highly schematically depicts a detailed view of a part of the electronics rack and a part of the electronics module; and

FIG. 5 highly schematically depicts a perspective view of a part of the electronics module.

### DETAILED DESCRIPTION

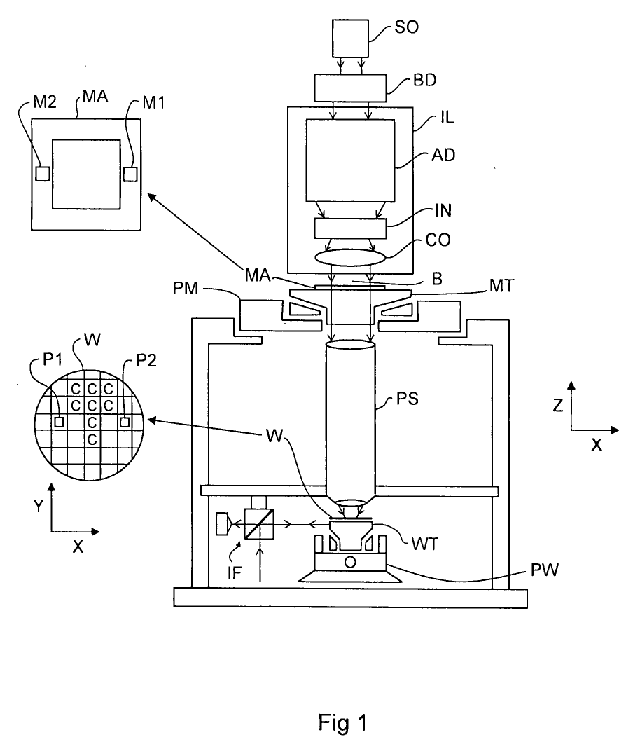

FIG. 1 schematically depicts a lithographic apparatus according to one embodiment of the invention. The apparatus includes an illumination system (illuminator) IL configured to condition a radiation beam B (e.g. UV radiation or any other suitable radiation), a patterning device support (e.g. a mask table) MT constructed to support a patterning device (e.g. a mask) MA and connected to a first positioning device PM configured to accurately position the patterning device in accordance with certain parameters. The apparatus also includes a substrate support (e.g. a wafer table) WT constructed to hold a substrate (e.g. a resist-coated wafer) W and connected to a second positioning device PW configured to accurately position the substrate in accordance with certain parameters. The apparatus further includes a projection system (e.g. a refractive projection lens system) PS configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, for directing, shaping, or controlling radiation.

The patterning device support holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support may be a frame or a table, for example, which may be fixed or movable as required. The patterning device support may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section so as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror-matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate supports (and/or two or more patterning device supports). In such “multiple stage” machines the additional supports may be used in parallel, or preparatory steps may be carried out on one or more supports while one or more other supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques can be used to increase the numerical aperture of projection systems. The term “immersion” as used herein does not mean that a structure, such as a substrate, must be submerged in liquid, but rather only means that a liquid is located between the projection system and the substrate during exposure.

Referring to FIG. 1, the illuminator IL receives a radiation beam from a radiation source SO. The source and the lithographic apparatus may be-separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator EL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as i-outer and i-inner, respectively) of the intensity distribution in a pupil plane of the illuminator can be adjusted. In addition, the illuminator IL may include various other components, such as an integrator, IN and a condenser CO. The illuminator may be used to condition the radiation beam, to have a desired uniformity and intensity distribution in its cross-section.

The radiation beam B is incident on the patterning device (e.g., mask MA), which is held on the patterning device support (e.g., mask table) MT, and is patterned by the patterning device. Having traversed the patterning device MA, the radiation beam B passes through the projection system PS, which focuses the beam onto a target portion C of the substrate W. With the aid of the second positioning device PW and position sensor IF (e.g. an interferometric device, linear encoder or capacitive sensor), the substrate table WT can be moved accurately, e.g. so as to position different target portions C in the path of the radiation beam B. Similarly, the first positioning device PM and another position sensor (which is not explicitly depicted in FIG. 1) can be used to accurately position the patterning device MA with respect to the path of the radiation beam B, e.g. after mechanical retrieval from a mask library, or during a scan. In general, movement of the patterning device support MT may be realized with the aid of a long-stroke module (coarse positioning) and a short-stroke module (fine positioning), which form part of the first positioning device PM. Similarly, movement of the substrate table WT may be realized using a long-stroke module and a short-stroke module, which form part of the second positioner PW. In the case of a stepper (as opposed to a scanner) the patterning device support MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus could be used in at least one of the following modes:

1. In step mode, the patterning device support MT and the substrate support WT are kept essentially stationary, while an entire pattern imparted to the radiation beam is projected onto a target portion C at one time (i.e. a single static exposure). The substrate support WT is then shifted in the X and/or Y direction so that a different target portion C can be exposed. In step mode, the maximum size of the exposure field limits the size of the target portion C imaged in a single static exposure.

2. In scan mode, the patterning device support MT and the substrate table WT are scanned synchronously while a pattern imparted to the radiation beam is projected onto a target portion C (i.e. a single dynamic exposure). The velocity and direction of the substrate support WT relative to the patterning device support MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the patterning device support MT is kept essentially stationary holding a programmable patterning device, and the substrate support WT is moved or scanned while a pattern imparted to the radiation beam is projected onto a target portion C. In this mode, generally a pulsed radiation source is employed and the programmable patterning device is updated as required after each movement of the substrate support WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

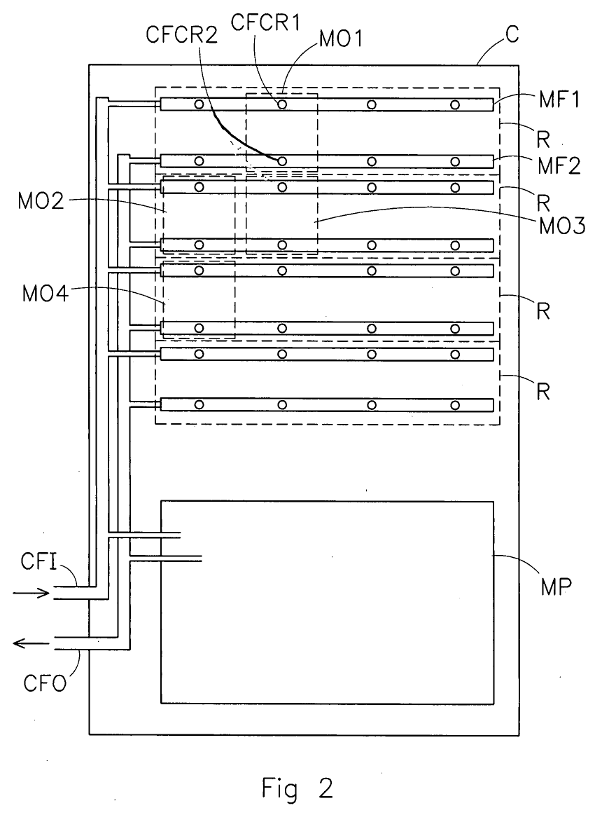

FIG. 2 shows a front view, partly in cross-section, of a highly schematic representation of an electronics cabinet C comprising a plurality of electronics racks R as may be applied in a lithographic apparatus. The cabinet C comprises a cooling fluid input CFI and a cooling fluid output CFO, which may lead to a heat exchanger, cooler or other device. Via the cooling fluid input, a cooling fluid may supplied into the cabinet and distributed towards a plurality of manifolds (which may be part of corresponding electronics racks), indicated here as manifold 1 MF1 and manifold 2 MF2. An electronics module, an example of which being highly schematically indicated by an interrupted line, and being referred to as MO1, may be mounted in the electronics rack, the electronics rack comprising a cooling fluid connector CFCR1 and a cooling fluid connector CFCR2, which may be connected to manifold 1 MF1 and manifold 2 MF2 respectively. Cooling fluid may thus be supplied via the cooling fluid input CFI towards an electronics module such as module MO1 placed in the rack R in the cabinet C, the respective electronics module being provided with cooling fluid by one or more respective connectors. A plurality of modules can be accommodated in each rack R, as shown in FIG. 2, each of the manifolds comprising, in this example, 4 fluid connectors. Further, 4 pairs of manifolds are provided, thus in this example 4 modules may be accommodated per rack, resulting in a total of 16 modules per cabinet. Further, one or more guide elements to guide a module into place on a rack R may be provided, such as a guide rail, a guide pin, etc. (which are not shown in FIG. 2 for clarity purposes).

In this example, the-cabinet C further comprises a power supply module, indicated here as MP. The power supply may provide electrical power (e.g. positive and/or negative supply voltage) to one or more of the modules. As an example of further modules which can be mounted in the rack R, in FIG. 2, modules MO2, MO3 and MO4 are highly schematically indicated by dotted lines.

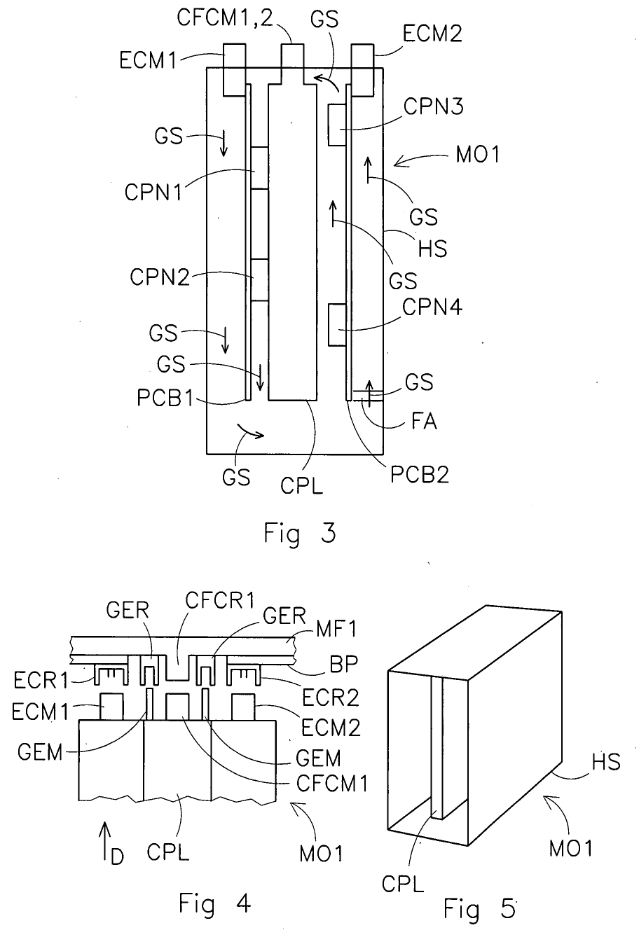

A top view of an example of a module, in a highly schematic cross sectional view, is shown in FIG. 3. FIG. 3 shows housing HS of module MO1, a cooling plate CPL which extends in the module MO1, and which is provided with cooling fluid connectors CFCM1 and CFCM2 respectively, to be able to establish a cooling fluid connection to mating cooling fluid connectors of the electronics rack R, e.g. cooling fluid connectors CFCR1 and CFCR2 respectively, as shown in FIG. 2. Further, the electronics module includes, in this example, 2 printed circuit boards, indicated here as PCB1 and PBC2 respectively. Each of the printed circuit boards PCB1, PCB2 is provided with an electronics connector ECM1 and ECM2 respectively, which respectively establish an electrical connection between the respective circuit boards PCB1, PCB2 of the module and mating electrical connectors of the electronics rack (which are not shown in detail in FIG. 2 for clarity purposes, but which will be discussed in more detail below with reference to FIG. 4). The cooling plate CPL may, in this example, include suitable cooling ducts which allow the cooling fluid entering the module MO1 via one of the cooling fluid connectors, CFCM1, CFCM2, to flow towards the other one of the cooling fluid connectors CFCM1, CFCM2. Electrical or electronic components to be cooled are brought in thermal contact with the cooling plate to allow exchange of heat towards the cooling plate CPL. Thermal contact can be achieved in a plurality of ways, as an example, such components may be mounted in the module in a position where a mechanical contact with the cooling plate CPL is achieved, for example, as is the case with components CPN1, CPN2 which are highly schematically shown in FIG. 3. Also, components may be mounted in a vicinity of the cooling plate, e.g. leaving a gap between the component in question and the cooling plate, as for example components CPN3 and CPN4 in FIG. 3. Other components (not shown), such as components having a relatively lower power dissipation, may be cooled in other ways: as an example, a gas circulation device may be provided in the module, such as a fan FA. Using the fan FA, gas may be circulated in the housing HS of the module MO1 to provide a gas stream along electric and/or electronic components as well as along the cooling plate CPL. Through the use of the gas stream, heat may be transferred from the components to the gas, and in turn the gas, when passing along the cooling plate CPL, may be cooled, thus transferring heat towards the cooling plate CPL. The gas circulation device, in this example the fan FA may be arranged in any of a number of ways. FIG. 3, as example, shows a set up where a gas stream GS may be provided towards and away from a side of the module where the cooling fluid connectors and electrical connectors are located. The housing HS forms in this embodiment a closed housing enclosing the cooling plate, which may provide one or more advantages such as prevention or reduction of contamination (such as substances released by the printed circuit boards, electronic components, etc in the module) of the clean environment in which the electronics are located, prevention or reduction of possible leakage into the surroundings of the module or from the surroundings into the module as may occur with a perforated module used in cooling applications where there is gas exchange with the surroundings outside of the module, and/or use of a specific, suitable gas mixture in the module (to, e.g., enhance reliability, prevent oxidation, improve heat exchange, etc. of the components in the module).

A connection between the module and the rack will now be discussed in more detail with reference FIG. 4, where an example of such a connection is depicted in more detail. FIG. 4 shows a more detailed, yet schematic view of a part of an electronics rack, showing a part of manifold MF1, as well as showing cooling fluid connector CFCR1. A back plane BP (comprising e.g. a printed circuit board) is provided in the rack and provided with electrical connectors ECR1 and ECR2. Via the back plane BP and the electrical connectors ECR1, ECR2, electrical contact may be established with a module connected to the respective connectors. Via the back plane, electrical connections may be established, for example, with other modules in the rack, modules of other racks, modules of other cabinets, and/or other parts of the lithographic apparatus, such as an actuator, a sensor, a control device, a processor, etc. The module MO1, as already depicted and described with reference to FIG. 3, comprises electrical connectors ECM1 and ECM2 respectively to establish an electric contact with the electrical connectors ECR1 and ECR2 respectively of the electronics rack. The module further comprises cooling fluid connectors, of which in this view cooling fluid connector CFCM1 is shown, enabling establishment of a cooling fluid connection with mating cooling fluid connector CFCR1 of the rack. A direction of insertion has been indicated by D in FIG. 4. A direction of insertion of the mating electrical connectors, i.e. mating electrical connectors ECR1 and ECM1 as well as mating electrical connectors ECR2 and ECM2, substantially corresponds to the direction of insertion D of the mating cooling fluid connectors CFCR1 and CFCM1, as well as, for example, CFCR2 and CFCM2 (not shown in FIG. 4 for clarity). By having substantially the same directions of insertion, the electrical connection and the cooling fluid connection can be established in a single operation, e.g. when inserting the module in the. direction D into the rack. It is thus to be understood that the direction of insertion of the cooling fluid connectors as well as the direction of insertion of the electrical connectors substantially correspond to the direction of insertion D of the electronics module MO1.

In an embodiment, the electrical connector and the cooling fluid connector of the electronics rack are located in a plane perpendicular to the direction of insertion of the electronics connector, as is the case in the embodiment shown in FIG. 4. The plane is to be understood as a plane perpendicular to the direction of insertion of the electronics connector and the cooling fluid connector. Thus, the electrical connection and cooling fluid connection may be established at a same moment in time or the cooling fluid connection may be made prior to the electrical connection when mounting the module MO1. With this connection arrangement, an electrical connection may not be established before a cooling fluid connection has been established to avoid an adverse situation where power dissipation occurs (at the time of electrical connection) but there isn't sufficient cooling to keep the temperature of the electronic components in the module to a desired level. The cooling fluid connectors may be of a double shut-off type to prevent leakage of cooling fluid upon insertion/removal of the module in question. The cooling fluid connectors and the electrical connectors may be spaced apart in a horizontal direction to possibly prevent an accidental leakage of cooling fluid onto the electrical connectors. Mutually co-operating guide elements may be provided at the rack by respective guide elements GER, and at the module by respective guide elements GEM. Upon insertion of the module, the guide elements may guide the electronics module to provide an adequate positioning of the electrical connectors and cooling fluid connectors of the module and the rack with respect to each other, to help prevent damage, e.g. due to broken or deformed pins of the electrical connectors, leakage of the cooling fluid connectors by incorrect insertion, etc.

In this embodiment, the guide elements of the rack GER are mechanically connected to a manifold, in this example a manifold MF1, to provide for an actual positioning of the module with reference to the cooling fluid connectors. In other words the manifold may function as a reference: the cooling fluid connectors CFCR1, CFCR2 of the rack are positioned with respect to the reference and upon insertion of the module, the mutually co-operating guide elements of the module and the rack, will position the cooling fluid connector of the module in a correct position with respect to the cooling fluid connector of the rack. At the module, the guide elements GEM may be connected to the cooling plate CPL, to which also the cooling fluid connectors CFCM1, CFCM2 of the module may be connected, to provide an adequate positioning of the cooling fluid connectors of the module, with respect to the guide elements of the module, and hence with respect to the cooling fluid connector of the rack upon insertion.

To provide an adequate positioning of the electrical connectors, the electrical connectors of the electronics rack are provided on the back plane BP, the back plane being mechanically connected to the manifold so that the manifold may serve as a reference for the positioning of the electrical connectors also. Thus, when the module is inserted, the mutually co-operating guide elements of the rack and the module may provide for an adequate positioning of the cooling fluid connectors and electrical connectors of the module and the rack with respect to each other.

FIG. 5 shows a highly schematic perspective view of the module MO1 having the housing HS and the cooling plate CPL. A front part of the housing HS (i.e. a part of the housing directed towards the reader) has been left off the drawing for illustrative purposes so that the cooling plate CPL can be observed. Other elements of the module have also been left off the drawing (e.g. printed circuit boards, electronic components, guide rails, etc.) for clarity. As can be seen in FIG. 5, the cooling plate CPL extends in a vertical direction, i.e. when the module is inserted in the rack, the cooling plate extends in the vertical direction. Thus, a cooling fluid circulation may be provided in a vertical direction, e.g. from cooling fluid connector CFCR1 to cooling fluid connector CFCR2 as shown in FIG. 2, to allow for an adequate heat exchange. Heat generated in the module tends to move upwardly, thus possibly providing for a counter flow of heated and cooling fluid with respect to each other. A gap may be provided between the cooling plate and the housing, e.g. at a top side and a bottom side respectively thereof and/or at a front side and back side thereof, to allow the gas circulation device, such as the fan FA depicted in FIG. 3, to generate a gas circulation around the cooling plate CPL or a part thereof. Many other alternative set-ups may be provided, such as a horizontally positioned cooling plate, a cooling body having a shape different from a plate, etc.

The combination of an electronics module and electronics rack as described above may not only be used in a lithographic apparatus. The above concept or parts thereof may be advantageously used in any application, for example, where it is desired to provide high power modules having a relatively high power dissipation and/or a high power density within an electronics rack.

The terms electrical, electronic or electronics as used herein should be understood in a broad sense, e.g. referring to any electrical or electronic application. The electrical connector may thus establish electrical connection to any electrical and/or electronic part, component, circuit, device, indicator, actuator, sensor, data processing unit (such as a micro-controller or microprocessor), memory, or other electrical and/or electronic device. It is to be understood that the term electronics rack does not necessarily imply that the rack itself comprises electronics. The electrical and/or electronics device may or may not be provided in the module or modules in the rack.

The cooling fluid may comprise any cooling fluid, such as a cooling liquid or a cooling gas. As a example, ultra pure water (a water having a conductivity lower than 1 microSiemens per centimeter) may be applied as a cooling fluid to help prevent corrosion problems, etc. in the manifold, cooling plate and/or other parts. Any suitable type of cooling fluid connector may be used.

Although in the above examples the racks are placed in a cabinet, other configurations may be used. The invention is not to be understood as to be limited to the shown embodiments. The term rack is to be understood as comprising any holding device to hold and/or establish a connection with an electronics module.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm), as well as particle beams, such as ion beams or electron beams. The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

What is claimed is:

1. A lithographic apparatus comprising:
an illumination system configured to condition a radiation beam;
a support constructed to support a patterning device, the patterning device configured to impart the radiation beam with a pattern in its cross-section to form a patterned radiation beam;
a substrate support constructed to hold a substrate;
a projection system configured to project the patterned radiation beam onto a target portion of the substrate; and
an electronics module and an electronics rack in which the electronics module is operationally housed, the electronics rack comprising an electrical connector to establish an electrical connection to a mating electrical connector of the electronics module and a cooling fluid connector to establish a cooling fluid connection to a mating cooling fluid connector of the electronics module, wherein a direction of insertion of the mating electrical connector substantially corresponds to a direction of insertion of the mating cooling fluid connector.

2. The apparatus of claim 1, wherein the electrical connector and the cooling fluid connector of the electronics rack are located in a plane perpendicular to the direction of insertion of the mating electronics connector.

3. The apparatus of claim 1, wherein the electronics rack comprises a manifold to distribute the cooling fluid to a plurality of electronics module slots provided in the electronics rack.

4. The apparatus of claim 3, wherein the electronics rack and the electronics module each comprise a mutually cooperating guide element to guide the electronics module upon insertion in the rack, the guide element of the electronics rack being connected to the manifold.

5. The apparatus of claim 3, wherein the electrical connector of the electronics rack is provided on an electrical backplane of the electronics rack, the electrical backplane mechanically connected to the manifold.

6. The apparatus of claim 1, wherein the electronics module comprises a cooling plate having fluid channels configured to circulate the cooling fluid.

7. The apparatus of claim 6, wherein the electronics module comprises a closed housing enclosing the cooling plate.

8. The apparatus of claim 6, wherein the electronics module comprises a gas circulation device to generate a gas circulation in the electronics module along at least a part of the cooling plate.

9. The apparatus of claim 6, wherein the cooling plate extends in the electronics module along a vertical direction.

10. The apparatus of claim 6, wherein the electronics module comprises a guide element to guide the electronics module upon insertion in the rack, the guide element of the electronics module connected to the cooling plate.

11. A combination of an electronics module and an electronics rack to operationally accommodate the electronics module, the electronics rack comprising an electrical connector to establish an electrical connection to a mating electrical connector of the electronics module and a cooling fluid connector to establish a cooling fluid connection to a mating cooling fluid connector of the electronics module, wherein a direction of insertion of the mating electrical connector substantially corresponds to a direction of insertion of the mating cooling fluid connector.

12. The combination of claim 11, wherein the electrical connector and the cooling fluid connector of the electronics rack are located in a plane perpendicular to the direction of insertion of the mating electronics connector.

13. The combination of claim 11, wherein the electronics rack comprises a manifold to distribute the cooling fluid to a plurality of electronics module slots provided in the electronics rack.

14. The combination of claim 13, wherein the electronics rack and the electronics module each comprise a mutually cooperating guide element to guide the electronics module upon insertion in the rack, the guide element of the electronics rack connected to the manifold.

15. The combination of claim 13, wherein the electrical connector of the electronics rack is provided on an electrical backplane of the electronics rack, the electrical backplane mechanically connected to the manifold.

16. The combination of claim 11, wherein the electronics module comprises a cooling plate having fluid channels configured to circulate the cooling fluid.

17. The combination of claim 16, wherein the electronics module comprises a closed housing enclosing the cooling plate.

18. The combination of claim 17, wherein the electronics module comprises a gas circulation device to generate a gas circulation in the electronics module along at least a part of the cooling plate.

19. The combination of claim 16, wherein the cooling plate extends in the electronics module along a vertical direction.

20. The combination of claim 16, wherein the electronics module comprises a guide element to guide the electronics module upon insertion in the rack, the guide element of the electronics module connected to the cooling plate.

21. An electronics module to be operated in an electronics rack, the electronics module comprising an electrical connector to establish an electrical connection to a mating electrical connector of the electronics rack and a cooling fluid connector to establish a cooling fluid connection to a mating cooling fluid connector of the electronics rack, wherein a direction of insertion of the electrical connector of the electronics module substantially corresponds to a direction of insertion of the cooling fluid connector of the electronics module.

22. The module of claim 21, wherein the electronics module comprises a cooling plate having fluid channels to circulate the cooling fluid.

23. The module of claim 22, wherein the electronics module comprises a closed housing enclosing the cooling plate.

24. The module of claim 22, wherein the electronics module comprises a gas circulation device to generate a gas circulation in the electronics module along at least a part of the cooling plate.

25. The module of claim 22, wherein the cooling plate extends in the electronics module along a vertical direction, electronic circuits being in thermal contact with a face of the cooling plate to exchange heat.

26. The module of claim 22, wherein a guide element of the electronics module is connected to the cooling plate and configured to co-operate with a guide element of the electronics rack.
